(19) United States
(12) Patent Application Publication
(10) Pub. No.: US 2025/0107410 A1
(43) Pub. Date: Mar. 27, 2025

(54) DISPLAY MODULE AND METHOD FOR PREPARING SAME, AND DISPLAY DEVICE

(71) Applicant: BOE Technology Group Co., Ltd., Beijing (CN)

(72) Inventors: Wenqing XUE, Beijing (CN); Renquan GU, Beijing (CN); Wusheng LI, Beijing (CN); Qi YAO, Beijing (CN); Huili WU, Beijing (CN); Shipei LI, Beijing (CN); Wei HE, Beijing (CN); Jianjun ZHAO, Beijing (CN); Yongfeng ZHANG, Beijing (CN); Chaolu WANG, Beijing (CN)

(73) Assignee: BOE Technology Group Co., Ltd., Beijing (CN)

(21) Appl. No.: 18/289,577

(22) PCT Filed: Dec. 5, 2022
(86) PCT No.: PCT/CN2022/136656

§ 371 Date: Nov. 6, 2023

(51) Int. Cl. H10K 59/80; H10K 59/12; H10K 59/121

(52) U.S. Cl. CPC H10K 59/879; H10K 59/1201; H10K 59/1213; H10K 59/873

(57) ABSTRACT

Provided is a display module, including a base substrate, a plurality of light-emitting patterns, and a plurality of microlens groups corresponding to the light-emitting patterns. An orthographic projection region of at least one of the light-emitting patterns on the base substrate forms a primary display region. The plurality of microlens groups are disposed on a side, distal from the base substrate, of the plurality of light-emitting patterns. An orthographic projection of the microlens group on the base substrate is within the primary display region formed by the corresponding light-emitting pattern. The microlens group includes at least two microlens structures, and a gap is defined between any adjacent two microlens structures. The light-emitting pattern includes a target region. An orthographic projection of the target region on the base substrate is overlapped with an orthographic projection of the gap on the base substrate. The target region does not emit light.

### CROSS-REFERENCE TO RELATED APPLICATION

The present disclosure is a U.S. national stage of international application No. PCT/CN2022/136656, filed on Dec. 5, 2022, the content of which is herein incorporated by reference in its entirety.

### TECHNICAL FIELD

The present disclosure relates to the field of display technologies, and in particular, relates to a display module and a method for preparing the same, and a display device.

### BACKGROUND

Organic light-emitting diode (OLED) display panels are widely used in the display field due to their advantages of self-luminescence, low energy consumption, low cost, wide viewing angle, low drive voltage, and fast response. However, OLED display panels have lower brightness compared to other types of display panels.

### SUMMARY

Embodiments of the present disclosure provide a display module and a method for preparing the same, and a display device. The technical solutions are as follows.

According to some embodiments of the present disclosure, a display module is provided. The display module includes:
a base substrate;
a plurality of light-emitting patterns disposed on the base substrate, wherein an orthographic projection region of at least one of the light-emitting patterns on the base substrate forms a primary display region; and
a plurality of microlens groups corresponding to the plurality of light-emitting patterns, wherein the plurality of microlens groups are disposed on a side, distal from the base substrate, of the plurality of light-emitting patterns, an orthographic projection of the microlens group on the base substrate is within the primary display region formed by the corresponding light-emitting pattern, the microlens group includes at least two microlens structures, and a gap is defined between any adjacent two of the microlens structures in the microlens group;
wherein the light-emitting pattern includes a target region, wherein an orthographic projection of the target region on the base substrate is overlapped with an orthographic projection of the gap on the base substrate, and the target region does not emit light.

In some embodiments, the display module further includes a protection layer disposed on a side, distal from the base substrate, of the microlens structure.

In some embodiments, a refractive index of a material of the protection layer is less than a refractive index of the microlens structure; wherein the material of the protection layer includes at least one of an inorganic material and a conductive light transmissive material.

In some embodiments, a thickness of the protection layer is less than a height of the microlens structure.

In some embodiments, a surface, distal from the base substrate, of the microlens structure is a curved surface; wherein a distance between a side, distal from the base substrate, of the microlens structure and a side, distal from the base substrate, of the light-emitting pattern is equal to a radius of curvature of the microlens structure.

In some embodiments, an orthographic projection of the microlens structure on a reference plane is curved, wherein the reference plane is perpendicular to a bearing surface of the base substrate; and a ratio of a height of the microlens structure to a width of the orthographic projection of the microlens structure on the reference plane ranges from 1/7 to 1/2.

In some embodiments, the display module further includes an encapsulation film layer disposed on the side, distal from the base substrate, of the plurality of light-emitting patterns, wherein the encapsulation film layer is configured to encapsulate the plurality of light-emitting patterns; wherein a difference between a refractive index of the encapsulation film layer and a refractive index of the microlens structure is less than a difference threshold.

In some embodiments, in a same microlens group, an area of the orthographic projection of the gap on the base substrate is smaller than an area of an orthographic projection of the microlens structure on the base substrate.

In some embodiments, an orthographic projection of the microlens structure on the base substrate is not overlapped with the orthographic projection of the target region on the base substrate.

In some embodiments, the target region of the light-emitting pattern is doped with ions, and a conductivity of the target region is less than a conductivity of a region of the light-emitting pattern other than the target region.

In some embodiments, the ions include at least one of boron ions, phosphorus ions, argon ions, arsenic ions, and fluorine ions.

In some embodiments, at least one of the primary display regions includes at least two sub-display regions acquired by being partitioned by the target region; and a number of microlens structures included in a same microlens group is positively correlated with a number of sub-display regions acquired by partitioning the primary display region of the corresponding light-emitting pattern.

In some embodiments, the number of microlens structures included in the same microlens group is equal to the number of sub-display regions acquired by partitioning the primary display region of the corresponding light-emitting pattern.

In some embodiments, at least one of the primary display regions includes at least two sub-display regions acquired by being partitioned by the target region; and areas of orthographic projections of microlens structures included in a same microlens group on the base substrate are positively correlated with areas of orthographic projections of sub-display regions acquired by partitioning the primary display region of the corresponding light-emitting pattern.

In some embodiments, a number of microlens structures included in a same microlens group is positively correlated with an area of an orthographic projection of the primary display region of the corresponding light-emitting pattern on the base substrate.

In some embodiments, the plurality of light-emitting patterns include a plurality of first color light-emitting patterns, a plurality of second color light-emitting patterns, and a plurality of third color light-emitting patterns; and the plurality of microlens groups include a plurality of microlens groups in one-to-one correspondence to the plurality of first color light-emitting patterns, a plurality of second microlens groups in one-to-one correspondence to the plurality of second color light-emitting patterns, and a plurality of third microlens groups in one-to-one correspondence to the plurality of third color light-emitting patterns; wherein each of the first microlens groups includes an equal number of microlens structures, each of the second microlens groups includes an equal number of microlens structures, and each of the third microlens groups includes an equal number of microlens structures.

In some embodiments, at least one of the primary display regions includes at least two sub-display regions acquired by being partitioned by the target region; and the display module further includes a transistor device layer between the base substrate and the plurality of light-emitting patterns; wherein a plurality of transistors included in the transistor device layer form a plurality of pixel circuits, a number of the pixel circuits is greater than or equal to a number of the light-emitting patterns, and the pixel circuit is configured to drive at least one of the sub-display regions in one of the light-emitting patterns to emit light.

According to some embodiments of the present disclosure, a method for preparing a display module is provided. The method includes:
providing a base substrate;
forming a plurality of light-emitting patterns on the base substrate, wherein an orthographic projection region of at least one of the light-emitting patterns on the base substrate forms a primary display region;
forming a plurality of microlens groups corresponding to the plurality of light-emitting patterns on a side, distal from the base substrate, of the plurality of light-emitting patterns, wherein an orthographic projection of the microlens group on the base substrate is within the primary display region formed by corresponding the light-emitting pattern, the microlens group includes at least two microlens structures, and a gap is defined between any adjacent two of the microlens structures in the microlens group; and
implanting ions into a target region of the light-emitting pattern using the microlens structure as a mask, wherein an orthographic projection of the target region on the base substrate is overlapped with an orthographic projection of the gap on the base substrate.

In some embodiments, upon implanting the ions into the target region of the light-emitting pattern, further including: forming a protection layer on a side, distal from the base substrate, of the microlens structure; wherein a refractive index of a material of the protection layer is less than a refractive index of the microlens structure, and the material of the protection layer includes at least one of an inorganic material and a conductive light transmissive material; or the material of the protection layer is a metallic material, and upon implanting the ions into the target region of the light-emitting pattern, the method further includes: removing the protection layer.

According to some embodiments of the present disclosure, a display device is provided. The display device includes: a power supply assembly and a display module as described above; wherein the power supply assembly is configured to supply power to the display module.

### BRIEF DESCRIPTION OF DRAWINGS

For clearer descriptions of the technical solutions in the embodiments of the present disclosure, the following briefly introduces the accompanying drawings to be required in the descriptions of the embodiments. Apparently, the accompanying drawings in the following description show merely some embodiments of the present disclosure, and persons of ordinary skills in the art may still derive other drawings from these accompanying drawings without creative efforts.

FIG. 1 is a schematic diagram of converging light by a microlens structure according to some embodiments of the present disclosure;

FIG. 2 is a schematic diagram of converging light by another microlens structure according to some embodiments of the present disclosure;

FIG. 3 is a schematic diagram of accuracy and effect corresponding to a microlens structure and a light-emitting pattern according to some embodiments of the present disclosure;

FIG. 4 is a schematic diagram of a curve of an angle and light intensity according to some embodiments of the present disclosure;

FIG. 5 is a schematic diagram of a relation between a deviation size, an enhancement magnification, and a viewing angle according to some embodiments of the present disclosure;

FIG. 6 is a schematic structural diagram of a display module according to some embodiments of the present disclosure;

FIG. 7 is a schematic structural diagram of another display module according to some embodiments of the present disclosure;

FIG. 8 is a schematic diagram of a light-emitting pattern undoped with ions according to some embodiments of the present disclosure;

FIG. 9 is a schematic diagram of a light-emitting pattern doped with ions according to some embodiments of the present disclosure;

FIG. 10 is a schematic diagram of another light-emitting pattern doped with ions according to some embodiments of the present disclosure;

FIG. 11 is a schematic diagram of still another light-emitting pattern doped with ions according to some embodiments of the present disclosure;

FIG. 12 is a schematic diagram of yet still another light-emitting pattern doped with ions according to some embodiments of the present disclosure;

FIG. 13 is a schematic diagram of yet still another light-emitting pattern doped with ions according to some embodiments of the present disclosure;

FIG. 14 is a schematic diagram of yet still another light-emitting pattern doped with ions according to some embodiments of the present disclosure;

FIG. 15 is a schematic diagram of a curve of a viewing angle and light intensity according to some embodiments of the present disclosure;

FIG. 16 is a flowchart of a method for preparing a display module according to some embodiments of the present disclosure;

FIG. 17 is a flow chart of another method for preparing a display module according to some embodiments of the present disclosure;

FIG. 18 is a schematic diagram of forming an encapsulation film layer according to some embodiments of the present disclosure;

FIG. 19 is a schematic diagram of forming a microlens structure according to some embodiments of the present disclosure;

FIG. 20 is a schematic diagram of forming a protection layer according to some embodiments of the present disclosure;

FIG. 21 is a schematic diagram of doping ions with a microlens structure as a mask according to some embodiments of the present disclosure; and

FIG. 22 is a schematic structural diagram of a display device according to some embodiments of the present disclosure.

### DETAILED DESCRIPTION

The present disclosure is described in further detail with reference to the accompanying drawings, to clearly present the objects, technical solutions, and advantages of the present disclosure.

In the related art, a display side of an OLED display panel designed with a microlens structure that converges edge light toward a positive viewing angle direction, such that the brightness of the OLED display panel in the positive viewing angle direction is improved, and a utilization rate of light is improved.

However, the technical solution of the related art, which is limited by a preparation process of the microlens structure, is difficult to satisfy the requirement of an alignment accuracy of the microlens structure and a display region of a sub-pixel in the OLED display panel, and thus it is difficult to achieve the effect of improving the brightness by converging the light.

The 3D light field, virtual reality (VR) technology, and augmented reality (AR) technology have revolutionized many fields such as artificial intelligence, computer-aided design (CAD), graphic simulation, virtual communication, remote sensing, entertainment, simulation training, and other fields. As the prices of input and output devices continue to fall, the quality of video displays improves, and the practicability of various software increases, the applications of 3D light field, VR technology, and AR technology are bound to grow.

OLED display panels are widely used in the display field due to the advantages of self-luminescence, low energy consumption, low cost, wide viewing angle, low driving voltage, and fast response. However, a prominent drawback of OLED display panels compared to other types of display panels is their low brightness.

Currently, there are several solutions to improve the brightness of OLED display panels.

1. The brightness of the OLED display panel is improved by enhancing the luminance of light-emitting devices in the OLED display panel, which is achieved by improving light-emitting (EL) materials of the light-emitting devices or by increasing current densities. However, both of these improvements are limited by the current state of technology, and thus there is limited room for improvement.

2. The brightness of the OLED display panel is improved by enhancing a transmission rate of a thin film encapsulation (TFE) 104 used to encapsulate light-emitting devices in the OLED display panel. However, the transmittance rate of the existing TFE is already very high (which is greater than 90%), so it is more difficult to have a greater breakthrough in the near future.

3. In the case that the OLED display panel emits light in the form of a white organic light-emitting diode and a color film (WOLED+CF), a transmittance rate of the color film is only about 30%, which has a large impact on the brightness of the OLED display panel. Therefore, the brightness of the OLED display panel is improved by enhancing the transmittance rate of the color film. However, the current level of the transmittance rate of the color film has reached the limit, which has little room for improvement, and the transmittance rate is mainly related to the material of the color film itself, which is difficult to have a big breakthrough in the research and development of the material.

4. The brightness of the OLED display panel is improved by causing each sub-pixel in the OLED display panel to emit light independently. For example, the OLED display panel includes red (R) sub-pixels, green (G) sub-pixels, and blue (B) sub-pixels, wherein the red sub-pixels emit red light, the green sub-pixels emit green light, and the blue sub-pixels emit blue light. Because there is no need to design a color film, this solution of emitting light from independent sub-pixels reduces the brightness loss by at least 60% compared to the solution of white light and color film. However, this solution has an obvious disadvantage: in the case of high pixels per inch (PPI) requirements, a size of a light-emitting pattern of the sub-pixel is small, and therefore, when a mask is used for evaporation preparation, the mask requires a high degree of precision. However, the current preparation level of the mask is difficult to achieve the preparation of the display panel with high PPI. For example, 3D light field, VR technology, and AR technology all require a resolution of more than 1000 PPI, but the resolution of a display panel prepared by evaporation using a mask only reaches a maximum of 500 PPI, which is mainly because the mask used for evaporation is unable to prepare a light-emitting pattern of less than 30 micrometers (μm), and the cost of the preparation is high, which makes it difficult to meet the demand.

That is, several of the above solutions for improving the brightness of OLED display panels suffer from various problems. The embodiments of the present disclosure improve light extraction or light enhancement by adding some new microlens structures, which is very effective for improving the luminance efficiency. Moreover, because the microlens structure is designed independently of the light-emitting device itself, the microlens structure has strong independent practicality. A light-emitting device is a device capable of emitting light composed of film layers between an anode layer and a cathode layer. The film layers between the anode layer and the cathode layer include, in addition to a light-emitting pattern, a hole injection layer, a hole transport layer, an electron block layer, an auxiliary function layer, a hole block layer, an electron transport layer, and an electron injection layer.

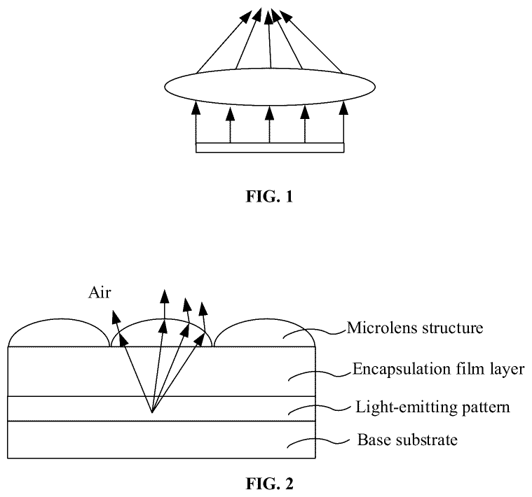

Referring to FIG. 1 and FIG. 2, a principle of using the microlens structure to improve the brightness is to converge edge light and make the light converge in a positive viewing angle by a light gathering effect, such that the brightness in a positive viewing angle direction is increased, and thus a light utilization is improved. In another aspect, an exit angle of the light is changed by designing the microlens structure, such that a total reflection of the light is reduced, and thus the light extraction is improved.

In some embodiments, a method for processing the microlens structure includes: 1. preparing to acquire the microlens structure first, after which directly attaching the microlens structure to a side, distal from a base substrate, of the light-emitting pattern; 2. nanoimprint; and 3. photolithographic thermal reflow. The above three processing methods are to prepare the microlens structure on the prepared light-emitting pattern, and to improve the luminance efficiency by aligning the light-emitting pattern with the microlens structure. The alignment accuracy of the first two processing methods is poor, and the processing difficulty and cost are high. Compared to the first two processing methods, the processing method of photolithographic thermal reflow has improved the alignment accuracy and lowered the cost, but there still exists an alignment (overlay) deviation, and thus a complete alignment fails to be achieved.

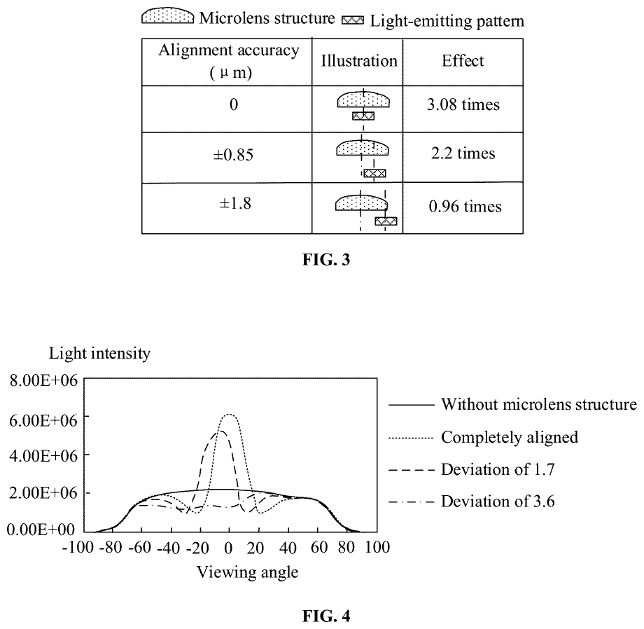

However, the magnitude of the alignment deviation between the microlens structure and a light-emitting region in the OLED display panel has a large impact on the enhancement of the luminance efficiency. Referring to FIG. 3 and FIG. 4, in the case that the microlens structure is not designed, the light intensity of the OLED display panel is small, i.e., the brightness is low; in the case that the microlens structure and the light-emitting region in the OLED display panel are completely aligned (the alignment accuracy is 0 μm), the brightness enhancement effect of the OLED display panel is up to 3.08 times; in the case that the microlens structure and the light-emitting region in the OLED display panel have a small alignment deviation (the alignment accuracy is ±0.85 μm in the figures), the brightness enhancement effect of the OLED display panel reaches 2.2 times (with some enhancement effect); and in the case that the alignment deviation between the microlens structure and the light-emitting region in the OLED display panel is large (the alignment accuracy is ±1.8 μm in the figures), the brightness enhancement effect of the OLED display panel is 0.96 times (with a reduction of brightness). In vertical coordinates of light intensity in FIG. 4, 2.00 E+06 indicates 2×106, 4.00 E+06 indicates 4×106, and so one, which are not repeated herein.

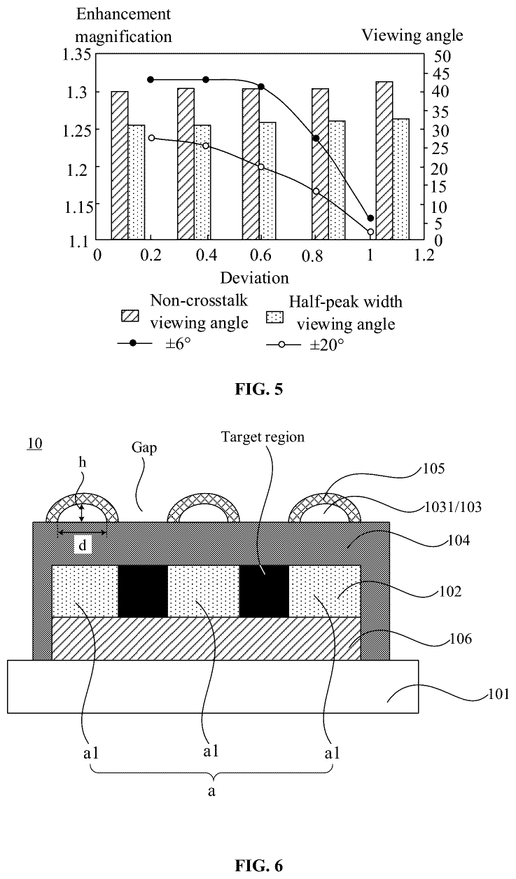

Still referring to FIG. 5, the brightness enhancement effect of the OLED display panel decreases with the increase of the alignment deviation. That is, the larger the alignment deviation is, the smaller the brightness of the OLED display panel is; and the smaller the alignment deviation is, the larger the brightness of the OLED display panel is. In addition, the smaller an included angle between the viewing angle and the positive viewing angle, the better the brightness enhancement effect. For example, the included angle of +6° means a greater enhancement magnification relative to ±20°. A non-crosstalk viewing angle and a half-peak width viewing angle both increase slightly with the increase of the alignment deviation (both are greater than 30)°. To achieve a brightness enhancement effect, it is necessary to make the alignment deviation less than 0.4 μm. In FIG. 5, horizontal coordinates of deviation indicate the alignment deviation in the unit of μm.

Based on the above theoretical analysis, in the case that it needs to achieve a large degree of brightness enhancement effect by designing the microlens structure, it is crucial to make the microlens structure and the light-emitting region of the OLED display panel achieve the complete alignment.

FIG. 6 is a schematic structural diagram of a display module according to some embodiments of the present disclosure. Referring to FIG. 6, the display module 10 includes a base substrate 101, a plurality of light-emitting patterns 102, and a plurality of microlens groups 103. The plurality of light-emitting patterns 102 are disposed on the base substrate 101, and the plurality of microlens groups 103 are disposed on a side, distal from the base substrate 101, of the plurality of light-emitting patterns 102. Only one light-emitting pattern 102 and one microlens group 103 are illustrated in FIG. 1.

In some embodiments, an orthographic projection of at least one of the light-emitting patterns 102 on the base substrate 101 forms a primary display region a. The plurality of microlens groups 103 correspond to the plurality of light-emitting patterns 102. An orthographic projection of the microlens group 103 on the base substrate 101 is within the primary display region a formed by the corresponding light-emitting pattern 102. The microlens group 103 includes at least two microlens structures (lenses) 1031, and a gap is defined between any adjacent two microlens structures 1031 in the microlens group 103.

In some embodiments, the orthographic projection of each of the light-emitting patterns 102 on the base substrate 101 forms a primary display region a, and the plurality of microlens groups 103 are in one-to-one correspondence to the plurality of light-emitting patterns 102. The orthographic projection of each of the microlens groups 103 on the base substrate 101 is within the primary display region a formed by the corresponding one of the light-emitting patterns 102. For example, one light-emitting pattern 102 is illustrated in FIG. 6, and the microlens group 103 corresponding to the light-emitting pattern 102 includes three microlens structures 1031.

In some embodiments, the light-emitting pattern 102 includes a target region, which does not emit light. An orthographic projection of the target region on the base substrate 101 is overlapped with an orthographic projection of the gap between the microlens structures 1031 on the base substrate 101. For example, the orthographic projection of the target region on the base substrate 101 and the orthographic projection of the gap between the microlens structures 1031 on the base substrate 101 are completely overlapped. That is, the target region of the light-emitting pattern 102 is a region where an orthographic projection of the gap between the microlens structures 1031 on the light-emitting pattern 102 is disposed.

The target region of the light-emitting pattern 102 does not emit light, while other regions of the light-emitting pattern 102 other than the target region emit light normally, such that the target region of the light-emitting pattern 102 is overlapped with the gap between the microlens structures 1031, and thus the alignment accuracy of a normal light-emitting region of the light-emitting pattern 102 and the microlens structure 1031 is improved. Further, an effect of the microlens structure 1031 converging the light emitted from the normal light-emitting region of the light-emitting pattern 102 is ensured, and thus the brightness of the display module 10 is improved.

In summary, the embodiments of the present disclosure provide a display module. The display module includes the plurality of light-emitting patterns and the microlens groups corresponding to the plurality of light-emitting patterns. The microlens group includes at least two microlens structures, and the gap is defined between any adjacent two microlens structures in the microlens group. The target region, corresponding to the gap of the microlens structures, in the light-emitting pattern does not emit light, and the region, corresponding to the microlens structure, in the light-emitting pattern emits light normally. In this way, the alignment accuracy of the microlens structure and the normal light-emitting region of the light-emitting pattern is ensured, such that the microlens structure is capable of converging the light, and thus the brightness of the display module is improved.

In some embodiments, the target region of the light-emitting pattern 102 is doped with ions, and the main function of the ions is to make the light-emitting material lose its light-emitting property by interrupting long conjugated chains in the light-emitting material. Therefore, a conductivity of the target region of the light-emitting pattern 102 is less than a conductivity of the region of the light-emitting pattern 102 other than the target region. An advantage of ion implantation is to precisely control a total dose, depth distribution, and surface uniformity of impurities. A range of ion implantation decreases with the increase of atomic number, and different ions are selected according to a thickness of the light-emitting pattern 102. For example, the ion is at least one of boron ions (B+), phosphorus ions (P+), argon ions (Ar+), arsenic ions (As+), and fluoride ions (F+).

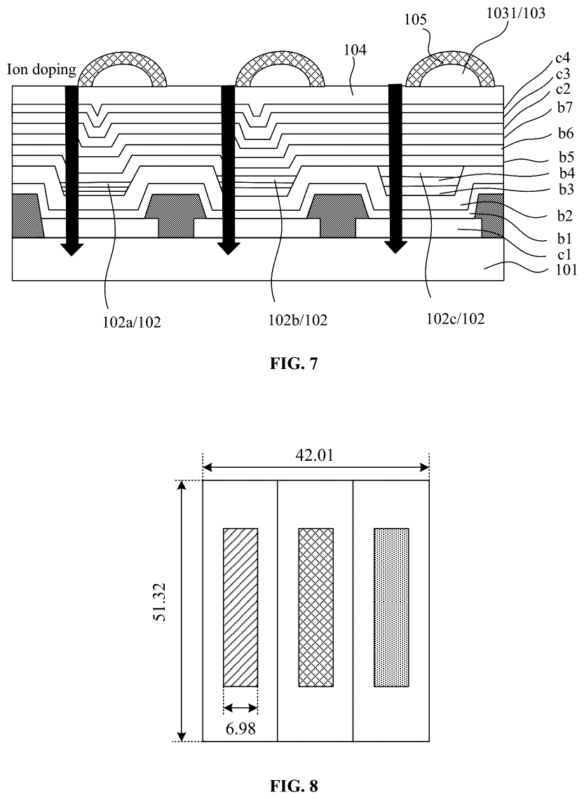

Referring to FIG. 7, the plurality of light-emitting patterns 102 of the display module 10 include a plurality of first color-emitting patterns 102a, a plurality of second color-emitting patterns 102b, and a plurality of third color-emitting patterns 102c. Film layers of the display module 10 disposed in a region where each color light-emitting pattern 102 is disposed further include a hole injection layer (HIL) b1, a hole transport layer (HTL) b2, an auxiliary function layer (prime) b3, an electron block layer (EBL) b4, a hole block layer (HBL) b5, an electron transport layer (ETL) b6, and an electron injection layer (EIL) b7. The HIL b1, the HTL b2, the HBL b5, the ETL b6, and the EIL b7 are common layers. The auxiliary function layer b3, the light-emitting pattern 102, and the EBL b4 are film layer patterns.

The HIL b1 is generally made of a material whose highest occupied molecular orbital (HOMO) energy level best matches the indium tin oxide (ITO) work function. The HOMO energy level is altered by doping ions into the HIL b1, and thus the conductivity of the HIL b1 is reduced.

The HTL b2 requires high film morphology stability, and thus generally has a non-planar molecular structure, huge and high molecular weight substituents, rigid groups, and the like. The film structure is disrupted by doping ions to reduce its hole transport capacity.

The light-emitting pattern 102 is doped with ions. That is, high energy is injected to bombard and disrupt the molecular structure of the light-emitting material, such that specific regions do not emit light.

For the EIL b7 and the ETL b6, their HOMO energy levels or lowest unoccupied molecular orbital (LOMO) energy levels are changed by doping ions, and their thin film conductivities are reduced by changing the film morphological stability.

In some embodiments, the at least one primary display region a includes at least two sub-display regions a1 acquired by being partitioned by the target region. The number of microlens structures 1031 included in the same microlens group 103 is positively correlated with the number of sub-display regions a1 acquired by partitioning the primary display region a of the corresponding light-emitting pattern. That is, in the case that the number of sub-display regions a1 acquired by partitioning the primary display region a of the light-emitting pattern 102 is required to be greater, the number of microlens structures 1031 included in the same microlens group 103 is made to be greater; and in the case that the number of sub-display regions a1 acquired by partitioning the primary display region a of the light-emitting pattern 102 is required to be fewer, the number of microlens structures 1031 included in the same microlens group 103 is made to be fewer.

In some embodiments, the number of microlens structures 1031 included in the same microlens group 103 is equal to the number of sub-display region a1 acquired by partitioning the primary display region a of the corresponding light-emitting pattern. Moreover, the plurality of sub-display regions a1 acquired by partitioning the primary display region a formed by the light-emitting pattern 102 are in one-to-one correspondence to the microlens structures 1031 included in the microlens group 103 corresponding to that light-emitting pattern 102. The microlens group 103 illustrated in FIG. 6 includes three microlens structures 1031, and three sub-display regions a1 are illustrated.

Thus, the solution of the embodiments of the present disclosure is to acquire a plurality of small-sized sub-display regions a1 by doping ions into the target region of the large-sized light-emitting pattern 102. That is, a size of each normal light-emitting region is reduced from a size of the original primary display region a to a size of the partitioned sub-display region a1, which actually increases the number of display regions of the display module 10 (i.e., increases the pixel density of the display module 10). This solution reduces the difficulty of preparation relative to the solution of directly forming the smaller-sized light-emitting pattern 102 by evaporation.

In some embodiments, an area of an orthographic projection of the microlens structure 1031 included in the same microlens group 103 on the base substrate 101 is positively correlated with an area of an orthographic projection on the base substrate 101 of the sub-display region a1 acquired by partitioning the primary display region a of the corresponding light-emitting pattern 101. That is, in the case the area of the orthographic projection on the base substrate 101 of the sub-display region a1 acquired by partitioning the primary display region a of the light-emitting pattern 102 is required to be larger, the area of the orthographic projection of the microlens structure 1031 included in the same microlens group 103 on the base substrate 101 is made to be larger; and in the case that the area of the orthographic projection on the base substrate 101 of the sub-display region a1 acquired by partitioning the primary display region a of the light-emitting pattern 102 is required to be smaller, the area of the orthographic projection of the microlens structures 1031 included in the same microlens group 103 on the base substrate 101 is made to be smaller.

In some embodiments, the area of the orthographic projection of the microlens structure 1031 included in the same microlens group 103 on the base substrate 101 is greater than or equal to the area of the orthographic projection on the base substrate 101 of the sub-display region a1 acquired by partitioning the primary display region a of the corresponding light-emitting pattern.

For example, in the case that the two areas are equal, the orthographic projection of the microlens structure 1031 included in the microlens group 103 on the base substrate 101 covers the orthographic projection on the base substrate 101 of the sub-display region a1 acquired by partitioning the primary display region a of the corresponding light-emitting pattern, while does not cover the orthographic projection of the gap between adjacent microlens structures on the base substrate 101. Alternatively, in the case that the area of the orthographic projection of the microlens structure 1031 included in the same microlens group 103 on the base substrate 101 is greater than the area of the orthographic projection on the base substrate 101 of the sub-display region a1 acquired by partitioning the primary display region a of the corresponding light-emitting pattern, the orthographic projection of the microlens structure 1031 included in the microlens group 103 on the base substrate 101 covers the orthographic projection on the base substrate 101 of the sub-display region a1 acquired by partitioning the primary display region a of the corresponding light-emitting pattern and the orthographic projection of the gap between adjacent microlens structures on the base substrate 101.

Referring to FIG. 7, the display module 10 further includes an anode layer c1 disposed on a side, proximal to the base substrate 101, of the light-emitting pattern 102, a cathode layer c2 disposed on a side, distal from the base substrate 101, of the light-emitting pattern 102, a first capping layer (CPL) c3, and a second capping layer c4. The plurality of light-emitting patterns 102 share a corresponding cathode layer c2.

On the one hand, during the process that the light emitted from the light-emitting pattern 102 propagates toward the display side, a surface plasmonic effect exists at an interface attachment between a metal and a dielectric layer, which leads to a decrease in the luminance efficiency. This effect is suppressed by designing the first capping layer c3 and the second capping layer c4. On the other hand, the OLED device forms a Fabry-Pérot optical resonance cavity between the anode layer c1 and the cathode layer c2. This resonant cavity is adjusted by designing the first capping layer c3 and the second capping layer c4, such that the luminance efficiency is adjusted, and the spectrum is selected.

Further, referring to FIG. 6 and FIG. 7, the display module 10 further includes an encapsulation film layer 104. Optionally, the encapsulation film layer 104 is configured to encapsulate a plurality of light-emitting patterns 102. A thickness of the encapsulation film layer 104 ranges from 2,000 angstroms (Å) to 12,000 Å.

A difference between a refractive index of the encapsulation film layer 104 and a refractive index of the microlens structure 1031 is less than a difference threshold. The difference between the refractive index of the encapsulation film layer 104 and the refractive index of the microlens structure 1031 refers to a value of the refractive index of the encapsulation film layer 104 minus the refractive index of the microlens structure 1031. Optionally, the difference threshold is 0.2. That is, the difference between the refractive index of the encapsulation film layer 104 and the refractive index of the microlens structure 1031 ranges from −0.2 to 0.2.

Because the difference between the refractive index of the encapsulation film layer 104 and the refractive index of the microlens structure 1031 is less than the difference threshold, the difference between the refractive index of the encapsulation film layer 104 and the refractive index of the microlens structure 1031 is small. In this way, the possibility that the light is reflected at an interface between the encapsulation film layer 104 and the microlens structure 1031 is reduced, such that the light is ensured to enter the microlens structure 1031, and thus the convergence of light is achieved.

In some embodiments, a surface, distal from the base substrate 101, of the microlens structure 1031 is a curved surface. To enable the light emitted from the light-emitting pattern 102 to converge at a center of the surface, distal from the base substrate 101, of the microlens structure 1031 as much as possible, a focal point of the microlens structure 1031 is made to fall at a position where the light-emitting pattern 102 is disposed. That is, a radius of curvature of the microlens structure 1031 is equal to a distance between a side, distal from the base substrate 101, of the microlens structure 1031 and a side, distal from the base substrate 101, of the light-emitting pattern 102.

The radius of curvature and distance are not strictly equal to each other, but rather have an allowable manufacturing process error. For example, the error is less than 0.5 μm. For example, a difference between the radius of curvature of the microlens structure 1031 and the distance between the side, distal from the base substrate 101, of the microlens structure 1031 and the side, distal from the base substrate 101, of the light-emitting pattern 102 ranges from −0.5 μm to 0.5 μm.

It should be noted that a height of the microlens structure 1031 and the radius of curvature of the microlens structure 1031 are both limited by the condition that the focal point of the microlens structure 1031 falls at the position where the light-emitting pattern 102 is disposed. The height of the microlens structure 1031 is equal to a difference between the radius of curvature of the microlens structure 1031 and a distance between a side, proximal to the base substrate 101, of the microlens structure 1031 and the side, distal from the base substrate 101, of the light-emitting pattern 102.

In some embodiments, referring to FIG. 6, a ratio of the height h of the microlens structure 1031 to a width d of an orthographic projection of the microlens structure 1031 on a reference plane ranges from 1/7 to 1/2, which facilitates the preparation of the microlens structure 1031. The reference plane is perpendicular to a bearing surface of the base substrate 101, and the orthographic projection of the microlens structure 1031 on the reference plane is curved.

In some embodiments, in the same microlens group 103, an area of the orthographic projection on the base substrate 101 of the gap between the microlens structures 1031 is less than an area of the orthographic projection of the microlens structure 1031 on the base substrate 101. Typically, the smaller the area of the orthographic projection of the gap between the microlens structures 1031 on the base substrate 101, the larger an aperture ratio, and thus the display effect of the display module is better. Thereby, a small aperture ratio due to a large gap between the microlens structures 1031 is avoided by causing the area of the orthographic projection of the gap between the microlens structures 1031 on the base substrate 101 to be smaller than the area of the orthographic projection of the microlens structure 1031 on the base substrate 101, such that the display effect of the display module is ensured.

In some embodiments, the gap between the microlens structures 1031 ranges from 2 μm to 4 μm. The width of the orthographic projection of the microlens structure 1031 on the reference plane ranges from 5 μm to 20 μm.

The width of the orthographic projection of the microlens structure 1031 on the reference plane and the gap between adjacent microlens structures 1031 are mainly determined by the size of the to-be-formed sub-display region of the display module and a spacing of the sub-display regions. Currently, the minimum size of the light-emitting pattern 103 formed by evaporation is 21 μm, while the partition method according to the embodiments of the present disclosure prepares a smaller size, and the microlens structure 1031 is matched accordingly. The higher the alignment accuracy of the microlens structure 1031 with the sub-display region, the larger the covered sub-display region, and thus the luminance efficiency is increased by a higher magnification. The embodiments ensure the alignment accuracy of the microlens structure 1031 with the sub-display region acquired by partitioning, such that luminance efficiency is maximized.

In some embodiments, an orthographic projection of the target region of the light-emitting pattern 102 on the base substrate 101 is overlapped with the orthographic projection of the gap between the microlens structures 1031 on the base substrate 101. Moreover, the orthographic projection of the microlens structure 1031 on the base substrate 101 is not overlapped with the orthographic projection of the target region on the base substrate 101. As a result, the regions of the light-emitting pattern 102 other than the target region (i.e., the plurality of sub-display regions a1) are made to be completely aligned with the microlens structures 1031, such that the light emitted from the sub-display region a1 is allowed to be converged through the microlens structure 1031, and thus the brightness of the display module 10 is improved.

Referring to FIG. 6 and FIG. 7, the display module 10 further includes a protection layer 105 disposed on the side, distal from the base substrate 101, of the microlens structure 1031. The protection layer 105 is configured to protect a surface of the microlens structure 1031 to avoid the surface damage of the microlens structure 1031.

In some embodiments, in the process of ion doping, ion beams are unable to penetrate the protection layer 105 to reach the surface of the microlens structure 1031, while in regions not covered by the microlens structure 1031, the ion beams are capable of penetrating the encapsulation film layer 104 to reach the light-emitting pattern. The reason why the ion beam cannot penetrate the protection layer 105 and can penetrate the encapsulation film layer 104 is that: the preparation processes of the two are different and material ratios of film layers of the two are also different. The protection layer 105 has a denser film quality compared to the encapsulation film layer 104.

A main difference between the protection layer 105 and the encapsulation film layer 104 is a film texture (i.e., a film layer texture). The film texture of the protection layer is denser and more effective in blocking ions.

In some embodiments, the encapsulation film layer 104 is prepared using chemical vapor deposition (CVD), and the protection layer 105 is prepared using plasma enhanced chemical vapor deposition (PECVD).

In some embodiments, a refractive index of a material of the protection layer 105 is less than the refractive index of the microlens structure 1031 and greater than a refractive index of the light when totally reflected at an interface between the microlens structure 1031 and the protection layer 105. As a result, the total reflection of the light at the interface between the microlens structure 1031 and the protection layer 105 is avoided, such that the light extraction effect is ensured.

Optionally, the protection layer 105 is made of at least one of an inorganic material and a conductive light transmissive material. That is, the protection layer 105 is made of an inorganic material, a conductive light transmissive material, or a mixture of an inorganic material and a conductive light transmissive material.

Exemplarily, the inorganic material includes at least one of silicon oxide (SiO) and silicon nitride (SiN). For example, the protection layer is a stacked structure of silicon oxide and silicon nitride. The conductive light transmissive material includes at least one of ITO or indium gallium zinc oxide (IGZO).

Alternatively, a thickness of the protection layer 105 is less than the height of the microlens structure 1031, such that the thickness of the protection layer 105 is avoided being too thick and affecting the exit of light. Exemplarily, the thickness of the protection layer 105 is greater than 3000 Å.

In some embodiments, the number of microlens structures 1031 included in the microlens group 103 is positively correlated with an area of an orthographic projection of the primary display region a of the corresponding light-emitting pattern 102 on the base substrate 101. That is, the larger the area of the orthographic projection of the primary display region a of the light-emitting pattern 102 on the base substrate 101, the greater the number of microlens structures 1031 included in the microlens group 103; and the smaller the area of the orthographic projection of the primary display region a of the light-emitting pattern 102 on the base substrate 101, the fewer the number of microlens structures 1031 included in the microlens group 103.

Typically, in the same display module, different light-emitting patterns 102 of the same color have the primary display regions a whose orthographic projections on the base substrate 101 have the same area, and thus the microlens groups 103 corresponding to different light-emitting patterns 102 of the same color have the same number of microlens structures 1031. As a result, different light-emitting patterns 102 of the same color have an equal number of sub-display regions a1, such that the display uniformity of the display module is ensured.

Exemplarily, the plurality of microlens groups 103 includes a plurality of first microlens groups in one-to-one correspondence to the plurality of first color-emitting patterns 102a, a plurality of second microlens groups in one-to-one correspondence to the plurality of second color-emitting patterns 102b, and a plurality of third microlens groups in one-to-one correspondence to the plurality of third color-emitting patterns 102c. Each of the first microlens groups includes an equal number of microlens structures. Each of the second microlens groups includes an equal number of microlens structures. Each of the third microlens groups includes an equal number of microlens structures. Alternatively, each of the first microlens groups includes a different number of microlens structures, each of the second microlens groups includes a different number of microlens structures, and each of the third microlens groups includes a different number of microlens structures, which are not limited herein.

Currently, the mainstream processing route of the light-emitting pattern is the evaporation method, and the display module required for the 3D light field display, VR display, and AR display requires a high resolution. In evaporating a high-resolution OLED light-emitting pattern, the pixel size is extremely small, and the required evaporation mask requires a very high accuracy, therefore, the preparation level of the mask directly limits this technical route, and there is no mass-producible solution yet. The embodiments of the present disclosure adopt the solution of ion implantation and pixel partition, using the ion implantation to achieve ion doping in a specific region, thereby changing the luminous property of the light-emitting material in the ion-doped region, such that the pixel partition is achieved without affecting the luminous property of the un-doped region, and thus the high-resolution OLED technology of Free-FMM (without a mask) is achieved.

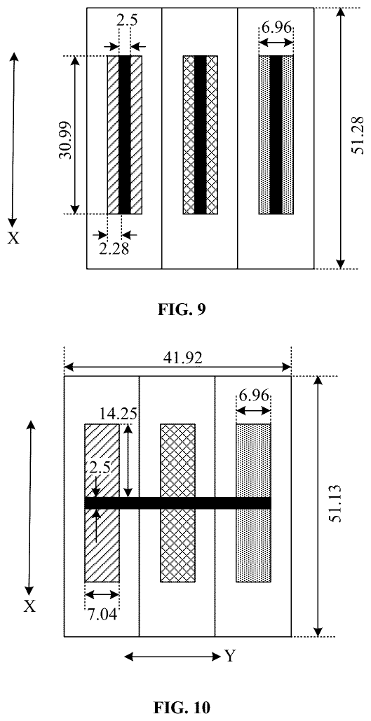

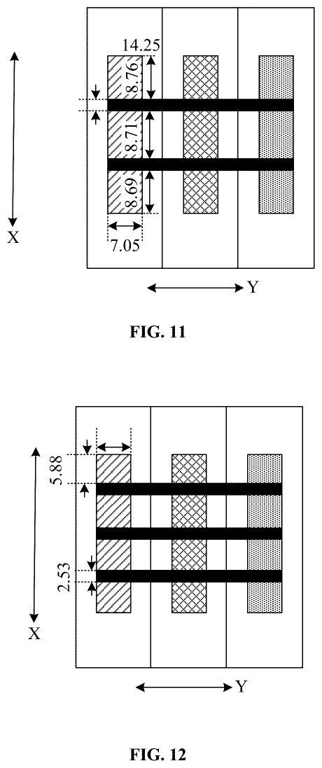

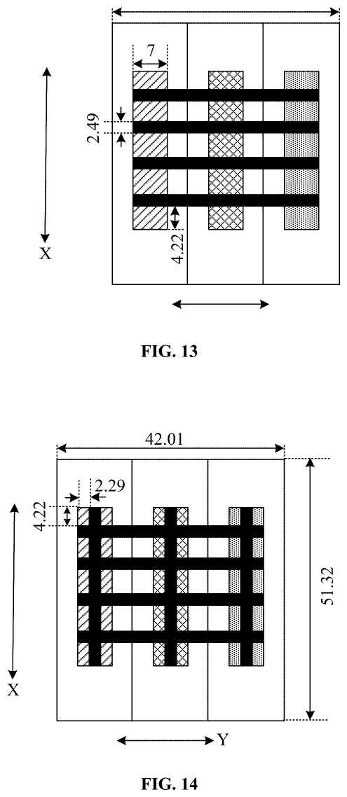

In conjunction with FIG. 8 to FIG. 13, the orthographic projections on the base substrate 101 of the light-emitting patterns 102 of three colors have the same area. Different fill patterns indicate light-emitting patterns of different colors. Referring to FIG. 9, the primary display region a formed by each of the light-emitting patterns 102 of different colors is partitioned into two sub-display regions a1 by a target region in the shape of a bar extending along a first direction X. Referring to FIG. 10, the primary display region a formed by each of the light-emitting patterns 102 of different colors is partitioned into two sub-display regions a1 by a target region in the shape of a bar extending along a second direction Y, and the target region of three colors form a connection region. Referring to FIG. 11, the primary display region a formed by each of the light-emitting patterns 102 of different colors is partitioned into three sub-display regions a1 by two target regions (a first target region and a second target region) in the shape of a bar extending along the second direction Y. The first target region of three colors forms a connection region, and the second target region of three colors forms a connection region. Referring to FIG. 12, the primary display region a formed by each of the light-emitting patterns 102 of different colors is partitioned into four sub-display regions a1 by three target regions (a first target region, a second target region, and a third target region) in the shape of a bar extending along the second direction Y. The first target region of three colors forms a connection region, the second target region of three colors forms a connection region, and the third target region of three colors forms a connection region. Referring to FIG. 13, the primary display region a formed by each of the light-emitting patterns 102 of different colors is partitioned into five sub-display regions a1 by four target regions (a first target region, a second target region, a third target region, and a fourth target region) extending along the second direction Y. The first target region of three colors forms a connection region, the second target region of three colors forms a connection region, and the third target region of three colors forms a connection region. Referring to FIG. 14, the primary display region a formed by each of the light-emitting patterns 102 of different colors is partitioned into ten sub-display regions a1 (five rows and two columns) by four target regions extending along the second direction Y and one target region extending along the first direction X. The first direction X in FIG. 8 to FIG. 14 is a lengthwise direction of the light-emitting pattern 102, and the second direction Y is a widthwise direction of the light-emitting pattern 102. FIG. 8 to FIG. 14 illustrate individual sizes, and each of the sizes is in the unit of μm. The individual sizes illustrated in FIG. 8 to FIG. 14 do not indicate actual sizes but are only simple illustrations to illustrate the pixel partition. A black fill indicates the target region, and a patterned fill indicates the sub-display region.

In some embodiments, the ion implantation has the advantage of precisely controlling the total dose, depth distribution, and surface uniformity of impurities. The pixel partition by ion implantation according to the embodiments of the present disclosure achieves the ion doping using the microlens structure 1031 as a block layer. That is, during the ion implantation, in the region covered by the microlens structure 1031, the ion beams are unable to penetrate the material of the microlens structure 1031, and at the same time, the inorganic layer on the surface of the microlens structure 1031 prevents the carbonized denaturation of the microlens structure 1031 and the damage of the morphology from affecting the luminance efficiency; and only in the region not covered by the microlens structure 1031, the ion beams are implanted into the light-emitting pattern 102 to achieve a certain concentration of doping, such that a fixed concentration of doping in a specific region is achieved.

The existing method of achieving pixel partition by ion implantation uses a photoresist as a block layer to achieve ion doping. The photoresist is utilized to protect the light-emitting material of the light-emitting pattern 102 by carbonizing to form a block layer during the ion implantation process, and the photoresist is removed using oxygen ashing or developing after the implantation is completed. The carbonized photoresist requires a long time for ashing, and a large number of particles are generated during ashing. Therefore, the ashed particles adhere to the surface of the encapsulation film layer 104, which is easy to damage the encapsulation film layer. Moreover, there is also a risk of a large amount of liquid entering the encapsulation film layer 104 during the development, causing failure of the light-emitting material.

Therefore, the embodiments of the present disclosure propose to use the microlens structure 1031 as a hard mask to block the ions, and at the same time, the protection layer 105 is prepared on the microlens structure 1031 to protect the surface morphology of the microlens structure 1031 from being damaged by the ion bombardment and prevent the surface from being carbonized and affecting the luminance efficiency.

Referring to FIG. 6, the display module 10 further includes a transistor device layer 106 between the base substrate 101 and the plurality of light-emitting patterns 102. A plurality of transistors included in the transistor device layer 106 form a plurality of pixel circuits. The number of pixel circuits is greater than or equal to the number of light-emitting patterns 102, and the pixel circuits are configured to drive at least one of the sub-display regions a1 of one of the light-emitting patterns 102 to emit light.

In some embodiments, in the case that the number of pixel circuits is equal to the number of light-emitting patterns 102, the pixel circuits are configured to drive all of the sub-display regions a1 in one of the light-emitting patterns 102 to emit light. In the case that the number of pixel circuits is greater than the number of light-emitting patterns 102, the pixel circuits are configured to drive at least one of the sub-display regions a1 in one of the light-emitting patterns 102 to emit light.

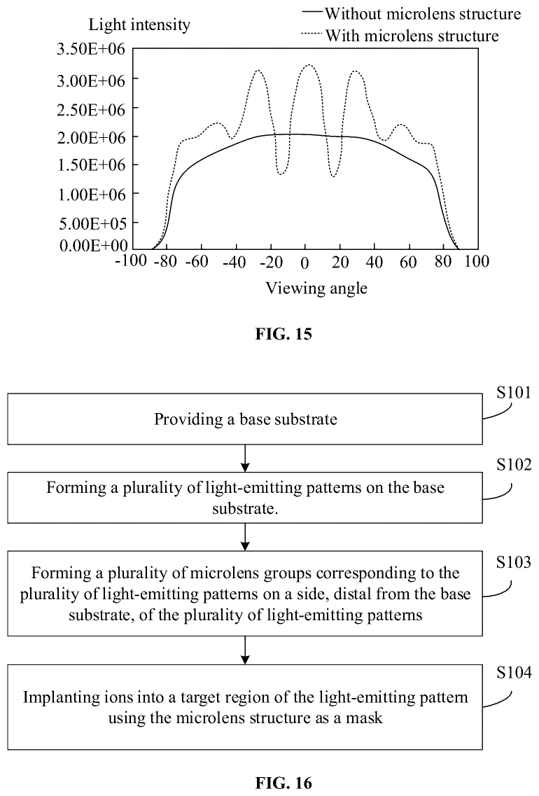

It should be noted that, referring to FIG. 15 and Table 1 below, the exiting intensity (the greater the intensity, the greater the luminance) of light is great at a position proximal to the positive viewing angle, and the intensity is small at a position slightly distal from the positive viewing angle. Moreover, the enhancement magnification of the brightness of the display module increases with the increase of the resolution of the display module.

In some embodiments, in vertical coordinates of light intensity in FIG. 15, 5.00 E+05 indicates 5×105, 1.00 E+06 indicates 1×106, and so on, which are not repeated herein.

The OLED display panel has the technical advantages of simple structure and high contrast ratio in achieving micro-display, and its disadvantage is low brightness. The AR product requires a high display resolution, and when the PPI increase, the aperture rate decreases, and the brightness decreases with the decrease of the aperture rate. For the product of a high aperture ratio, the microlens structure has a higher magnification for the luminance efficiency and is more capable of supporting high PPI products. In other words, based on FIG. 15 and Table 1, this display module is applied to high PPI display products, such as near-eye field display devices. For a near-eye field display device, the range of viewing angle is usually small and almost proximal to the positive viewing angle direction, so the brightness in the positive viewing angle direction needs to be increased as much as possible. Thus, the display module according to the embodiments of the present disclosure is precisely applicable.

TABLE 1

| | | Brightness | Brightness | |
|---|---|---|---|---|
| | | without | with | Brightness |
| Aperture | Resolution | microlens | microlens | enhancement |
| ratio | (PPI) | structure | structure | magnification |
| 60.30% | 3428.9 | 1500 | 2400 | 1.6 |
| 51.85% | 4248.2 | 1289.8 | 2386 | 1.85 |
| 44% | 5046.6 | 1094.5 | 2342 | 2.14 |
| 33.33% | 6199.9 | 829.1 | 2238 | 2.7 |

In some embodiments, there are several advantages of using the microlens structure 1031 as the mask for doping ions. 1. The brightness is substantially enhanced within a certain angle. 2. The alignment accuracy of the microlens structure 1031 and the light-emitting region has a great influence on the enhancement of the luminance efficiency. Because the present solution achieves the high-accuracy complete alignment of the microlens structure 1031 and the sub-display region (i.e., the light-emitting region), the luminance efficiency is maximized. 3. There is no need to remove the microlens structure 1031, such that there is no residue, and thus the damage to the encapsulation film layer 104 is small.

In summary, some embodiments of the present disclosure provide a display module. The display module includes the plurality of light-emitting patterns and the microlens groups corresponding to the plurality of light-emitting patterns. The microlens group includes at least two microlens structures, and the gap is defined between any adjacent two microlens structures in the microlens group. The target region, corresponding to the gap of the microlens structures, in the light-emitting pattern does not emit light, while the region, corresponding to the microlens structure, in the light-emitting pattern emits light normally. In this way, the alignment accuracy of the microlens structure and the normal light-emitting region of the light-emitting pattern is ensured, such that the microlens structure converges light, and thus the brightness of the display module is improved.

FIG. 6 is a schematic structural diagram of a display module according to some embodiments of the present disclosure. Referring to FIG. 16, the method includes the following steps.

In step S101, a base substrate is provided.

In some embodiments, in preparing the display module 10, a base substrate 101 is acquired first. The base substrate 101 is a glass substrate or a flexible substrate.

In step S102, a plurality of light-emitting patterns are formed on the base substrate.

In some embodiments, an orthographic projection of at least one of the light-emitting patterns 102 on the base substrate 101 forms a primary display region a.

In step S103, a plurality of microlens groups corresponding to the plurality of light-emitting patterns are formed on a side, distal from the base substrate, of the plurality of light-emitting patterns.

In some embodiments, an orthographic projection of the microlens group 103 on the base substrate 101 is within the primary display region formed by the corresponding light-emitting pattern 102 a. The microlens group 103 includes at least two microlens structures 1031, and a gap is defined between any adjacent two microlens structures 1031 in the microlens group 103.

In step S104, ions are implanted into a target region of the light-emitting pattern using the microlens structure as a mask.

In some embodiments, an orthographic projection of the target region on the base substrate 101 is overlapped with an orthographic projection of the gap between the microlens structures 1031 on the base substrate 101. For example, the target region is a region where an orthographic projection of the gap on the light-emitting pattern 102 is disposed.

Because the microlens structure 1031 is used as the mask in implanting the ions into the target region of the light-emitting pattern 102, the primary display region a includes at least two sub-display regions a1 partitioned by the target region. Moreover, the number of microlens structures 1031 included in the same microlens group 103 is equal to the number of sub-display regions a1 acquired by partitioning the primary display region a formed by the corresponding light-emitting pattern 102. The plurality of microlens structures 1031 included in the same microlens group 103 are in one-to-one correspondence to the plurality of sub-display regions a1 acquired by partitioning the primary display region a formed by the corresponding light-emitting pattern 102.

Because the target region of the light-emitting pattern 102 is doped with ions, which interrupt long conjugated chains in the light-emitting pattern 102 and make the light-emitting pattern 102 lose its light-emitting property, the target region of the light-emitting pattern 102 does not emit light. Regions (which are the plurality of sub-display region a1 acquired by partitioning the primary display region a) of the light-emitting pattern 102 other than the target region emit light normally.

As a result, a normal light-emitting region of the light-emitting pattern 102 (i.e., the sub-display region a1) and the microlens structure 1031 are completely aligned. That is, each of the sub-display regions a1 of the light-emitting pattern 102 is capable of being completely aligned with one of the microlens structures 1031, such that the microlens structure 1031 is capable of converging the light emitted from the corresponding sub-display region a1, and thus the brightness of the display module is improved.

Moreover, the embodiments of the present disclosure acquire the plurality of small-sized sub-display regions a1 by doping the ions into the target region of the large-sized light-emitting pattern 102. That is, a size of each of the normal light-emitting regions is reduced from a size of the original primary display region a to a size of the partitioned sub-display region a1, which actually increases the number of display regions of the display module (i.e., increases a pixel density of the display module). This solution reduces the difficulty of preparation as compared to the solution of directly forming the small-sized light-emitting pattern 102 by evaporation.

In summary, some embodiments of the present disclosure provide a method for preparing a display module. The display module includes the plurality of light-emitting patterns and the microlens groups corresponding to the plurality of light-emitting patterns. The microlens group includes at least two microlens structures, and the gap is defined between any adjacent two microlens structures in the microlens group. In the solution of the embodiments of the present disclosure, the ions are doped into the light-emitting pattern by using the microlens structure as the mask. Therefore, the target region, corresponding to the gap of the microlens structures, in the light-emitting pattern is doped with ions, while other regions are not doped with ions. As a result, the target region of the light-emitting pattern does not emit light while the regions of the light-emitting pattern other than the target region emit light normally. In this way, the microlens structure and the normal light-emitting region of the light-emitting pattern are completely aligned, such that the microlens structure converges light, and thus the brightness of the display module is improved.

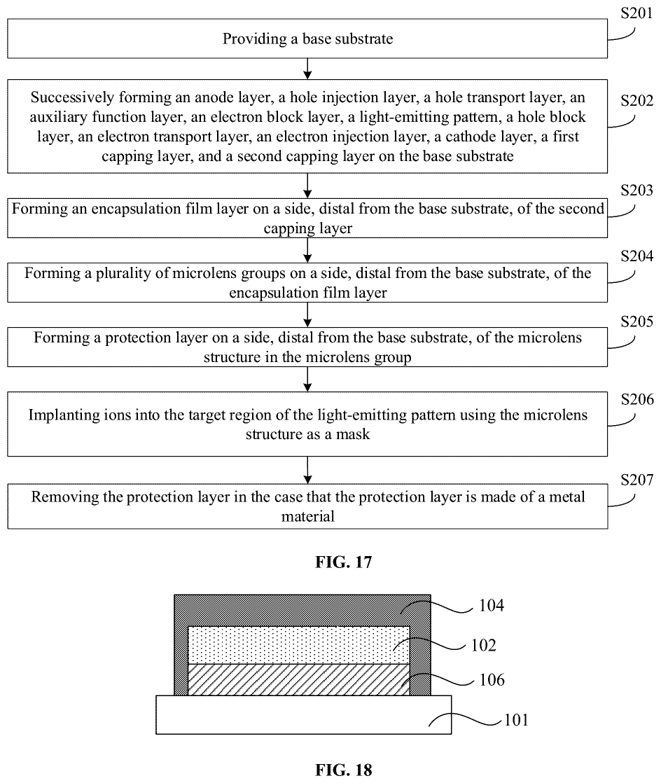

FIG. 17 is a flow chart of another method for preparing a display module according to some embodiments of the present disclosure. Referring to FIG. 17, the method includes the following steps. In step S201, a base substrate is provided.

In some embodiments, in preparing the display module 10, the base substrate 101 is acquired first. The base substrate 101 is a glass substrate or a flexible substrate.

In step S202, an anode layer, a hole injection layer, a hole transport layer, an auxiliary function layer, an electron block layer, a light-emitting pattern, a hole block layer, an electron transport layer, an electron injection layer, a cathode layer, a first capping layer, and a second capping layer are successively formed on the base substrate.

In some embodiments, the hole injection layer b1, the hole transport layer b2, the hole block layer b5, the electron transport layer b6, and the electron injection layer b7 are common film layers. The auxiliary function layer b3, the electron block layer b4, and the light-emitting pattern 102 are film layer patterns. Thus, in this step, a plurality of auxiliary function layers b3, a plurality of electron block layers b4, and a plurality of light-emitting patterns 102 are formed. The plurality of the light-emitting patterns 102 share a corresponding cathode layer. The first capping layer and the second capping layer serve to insulate water and oxygen.

An orthographic projection region of the light-emitting pattern 102 on the base substrate 101 forms a primary display region a.

In step S203, an encapsulation film layer is formed on a side, distal from the base substrate, of the second capping layer.

In some embodiments, referring to FIG. 18, the encapsulation film layer 104 is configured to encapsulate the plurality of light-emitting patterns 102.

In step S204, a plurality of microlens groups are formed on a side, distal from the base substrate, of the encapsulation film layer.

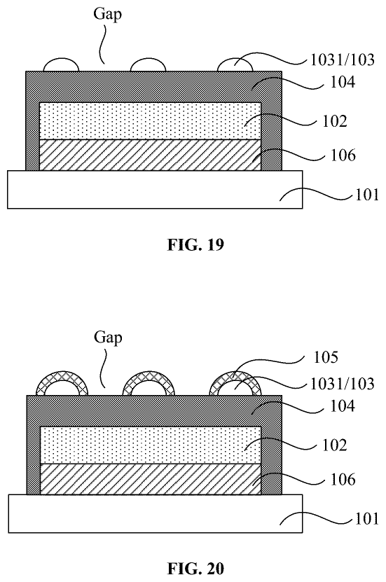

In some embodiments, the formed plurality of microlens groups 103 are in one-to-one correspondence to the formed plurality of light-emitting patterns 102. An orthographic projection of the microlens group 103 on the base substrate 101 is within the primary display region a formed by the corresponding light-emitting pattern 102. The microlens group 103 includes at least two microlens structures 1031, and a gap is defined between any adjacent two microlens structures 1031 in the microlens group 103. The microlens group 103 illustrated in FIG. 19 includes three microlens structures 1031.

In some embodiments, a difference between a refractive index of the microlens structures 1031 and a refractive index of the encapsulation film layer 104 formed in step S203 is less than a difference threshold. The difference between the refractive index of the encapsulation film layer 104 and the refractive index of the microlens structure 1031 is a value of the refractive index of the encapsulation film layer 104 minus the refractive index of the microlens structure 1031. Optionally, the difference threshold is 0.2. That is, the difference between the refractive index of the encapsulation film layer 104 and the refractive index of the microlens structure 1031 ranges from −0.2 to 0.2.

Because the difference between the refractive index of the encapsulation film layer 104 and the refractive index of the microlens structure 1031 is less than the difference threshold, the difference between the refractive index of the encapsulation film layer 104 and the refractive index of the microlens structure 1031 is as small as possible. In this way, the possibility that the light is refracted at an interface between the encapsulation film layer 104 and the microlens structure 1031 is reduced, such that the convergence effect of the microlens structure 1031 on the light is ensured.

In step S205, a protection layer is formed on a side, distal from the base substrate, of the microlens structure in the microlens group.

In some embodiments, referring to FIG. 20, the formed protection layer 105 is configured to protect a surface of the microlens structure 1031 in the microlens group 103. The protection layer 105 needs to be patterned to bare the gap between the microlens structures 1031.

In some embodiments, the protection layer 105 is made of at least one of an inorganic material and a conductive light transmissive material. In this case, because the inorganic material and the conductive light transmissive material are both transparent materials, there is no need to perform step S207. That is, there is no need to remove the protection layer 105. However, without removing the protection layer 105, it is necessary to ensure that the refractive index of the material of the protection layer 105 is less than the refractive index of the microlens structure 1031, such that the light is prevented from being totally reflected at an interface between the microlens structure 1031 and the protection layer 105, and thus the light extraction effect is ensured.

The inorganic material includes at least one of silicon oxide and silicon nitride. For example, the projection layer is a stacked structure of silicon oxide and silicon nitride. The conductive light transmissive material is at least one of ITO or IGZO.

In some embodiments, the protection layer 105 is made of a metallic material, such as molybdenum (Mo). In this case, because the metallic material is usually opaque, step S207 needs to be performed, such that the light is ensured to exit. That is, the protection layer 105 needs to be removed.

In step S206, ions are implanted into the target region of the light-emitting pattern using the microlens structure as a mask.

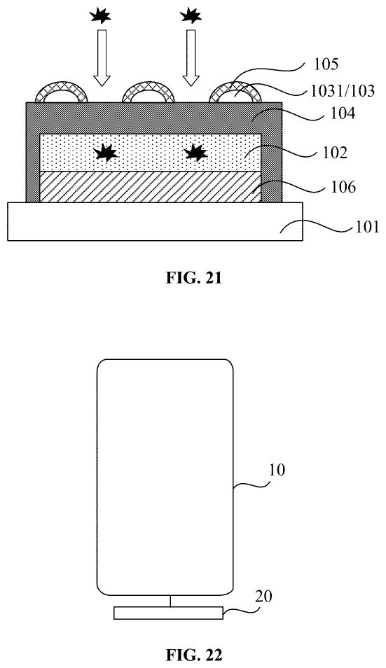

In some embodiments, referring to FIG. 21, the ions are implanted into the target region of the light-emitting pattern 102 using the microlens structure 1031 in the microlens group 103 as the mask, and the target region is a region where an orthographic projection of the gap between the microlens structures 1031 on the light-emitting pattern 102 is disposed. That is, an orthographic projection of the microlens structure 1031 on the base substrate 101 is not overlapped with an orthographic projection of the target region of the light-emitting pattern 102 on the base substrate 101. Thus, referring to FIG. 6, the primary display region a formed by the light-emitting pattern 102 includes at least two sub-display regions a1 partitioned by the target region. Moreover, the number of microlens structures 1031 included in the same microlens group 103 is equal to the number of sub-display regions a1 acquired by partitioning the primary display region a formed by the corresponding light-emitting pattern 102, and the plurality of microlens structures 1031 included in the same microlens group 103 are in one-to-one correspondence to the plurality of sub-display regions a1 acquired by partitioning the primary display region a formed by the light-emitting pattern 102.

Because the target region of the light-emitting pattern 102 is doped with ions, which interrupt long conjugated chains in the light-emitting pattern 102 and make the light-emitting pattern 102 lose its light-emitting property, the target region of the light-emitting pattern 102 does not emit light. Regions (which are the plurality of sub-display regions a1 acquired by partitioning the primary display region a) of the light-emitting pattern 102 other than the target region emit light normally.

A normal light-emitting region (i.e., the sub-display region a1) of the light-emitting pattern 102 and the microlens structure 1031 are completely aligned. That is, each of the sub-display regions a1 of the light-emitting pattern 102 is completely aligned with one of the microlens structures 1031, such that each of the microlens structures 1031 is capable of converging the light emitted from the corresponding sub-display region a1, and thus the brightness of the display module is improved.

Moreover, the embodiments of the present disclosure acquire the plurality of small-sized sub-display region a1 by doping ions into the target region of the large-sized light-emitting pattern 102. That is, a size of each of the normal light-emitting regions is reduced from a size of the original primary display region a to a size of the partitioned sub-display region a1, which actually increases the number of display regions of the display module (i.e., increases a pixel density of the display module). This solution reduces the difficulty of preparation as compared to the solution of directly forming the small-sized light-emitting pattern 102 by evaporation.

In step S207, the protection layer is removed.

In some embodiments, in the case that the protection layer 105 is made of an opaque metal material, the protection layer 105 needs to be removed after doping the ions using the microlens structure 1031 as the mask, such that the light is ensured to exit.

In summary, some embodiments of the present disclosure provide a method for preparing a display module. The display module includes the plurality of light-emitting patterns and the microlens groups corresponding to the plurality of light-emitting patterns. The microlens group includes at least two microlens structures, and the gap is defined between any adjacent two microlens structures in the microlens group. In the solution of the embodiments of the present disclosure, the ions are doped into the light-emitting pattern by using the microlens structure as the mask. Therefore, the target region, corresponding to the gap of the microlens structures, in the light-emitting pattern is doped with ions, while other regions are not doped with ions. As a result, the target region of the light-emitting pattern does not emit light while the regions of the light-emitting pattern other than the target region emit light normally. In this way, the microlens structure and the normal light-emitting region of the light-emitting pattern are completely aligned, such that the microlens structure converges light, and thus the brightness of the display module is improved.

FIG. 22 is a schematic structural diagram of a display device according to some embodiments of the present disclosure. Referring to FIG. 22, the display device includes a power supply assembly 20 and a display module 10 as provided in the above embodiments. The power supply assembly is configured to supply power to the display module 10.

In some embodiments, the display device is a near-eye field display device, such as a VR display device or an AR display device.

The display device has substantially the same technical effects as the wiring substrate described in the above embodiments. Therefore, the technical effects of the display device will not be repeated herein for brevity.

It should be understood that while the terms first and second may be used herein to describe various elements, components, regions, layers, and/or portions, these elements, components, regions, layers, and/or portions should not be limited by these terms. These terms are only used to distinguish one element, component, region, layer, or portion from another element, component, region, layer, or portion. Thus, the first element, component, region, layer, or portion discussed above may be referred to as a second element, component, region, layer, or portion without departing from the teachings of the present disclosure.

Spatially relative terms such as “below,” “above,” “left,” “right,” and the like may be used herein for ease of description to describe a relationship between one element or feature to another element(s) or feature(s) as illustrated in the figures. It will be understood that these spatially relative terms are intended to encompass different orientations of the device in use or operation in addition to the orientation depicted in the figures. For example, if the device in the figure is flipped, then an element described as “under another element or feature” will be oriented as “above another element or feature.” Thus, the exemplary term “under” may encompass both the orientation of above and the orientation of under. The device may be oriented in other ways (rotated 90 degrees or in other orientations) and the spatially relative terms used herein are interpreted accordingly. It will also be understood that when a layer is referred to as “between two layers”, it may be the only layer between the two layers, or there may be one or more intermediate layers.

Terms used herein are to describe particular embodiments only and are not intended to limit the present disclosure. As used herein, singular forms “a,” “an,” “one,” and “the” are intended to include the plural forms as well, unless the context clearly indicates otherwise. It will be further understood that the terms “include” and/or “comprise” or derivatives thereof when used in this specification indicate the presence of the described feature, whole, step, operation, element, and/or component, but do not exclude the presence of one or more other features, wholes, steps, operations, components, and/or groups thereof or the addition of one or more other features, wholes, steps, operations, components, and/or groups thereof. As used herein, the term “and/or”, as used herein in the specification and in the claims, should be understood to mean “either or both” of the elements so conjoined. In this specification, specific features, structures, materials, or characteristics described may be combined in any one or more embodiments or examples appropriately. In addition, without contradicting each other, those skilled in the art may combine different embodiments or examples and features of different embodiments or examples described in this specification.

Unless otherwise defined, all terms used herein, including technical and scientific terms, have the same meaning as is commonly understood by those skilled in the art to which this disclosure belongs. It will be further understood that terms such as those defined in commonly used dictionaries and the like should be interpreted as having a meaning consistent with their meaning in the relevant field and/or in the context of this specification, and will not be interpreted in an idealized or overly formal sense unless expressly defined herein.

Described above are merely exemplary embodiments of the present disclosure, and are not intended to limit the present disclosure. Therefore, any modifications, equivalent substitutions, improvements, and the like made within the spirit and principles of the present disclosure shall be included in the protection scope of the present disclosure.

1. A display module, comprising:
a base substrate;
a plurality of light-emitting patterns disposed on the base substrate, wherein an orthographic projection region of at least one of the light-emitting patterns on the base substrate forms a primary display region; and
a plurality of microlens groups corresponding to the plurality of light-emitting patterns, wherein the plurality of microlens groups are disposed on a side, distal from the base substrate, of the plurality of light-emitting patterns, an orthographic projection of the microlens group on the base substrate is within the primary display region formed by the corresponding light-emitting pattern, the microlens group comprises at least two microlens structures, and a gap is defined between any adjacent two of the microlens structures in the microlens group;
wherein the light-emitting pattern comprises a target region, wherein an orthographic projection of the target region on the base substrate is overlapped with an orthographic projection of the gap on the base substrate, and the target region does not emit light.

2. The display module according to claim 1, further comprising: a protection layer disposed on a side, distal from the base substrate, of the microlens structure.

3. The display module according to claim 2, wherein a refractive index of a material of the protection layer is less than a refractive index of the microlens structure;
wherein the material of the protection layer comprises at least one of an inorganic material and a conductive light transmissive material.

4. The display module according to claim 2, wherein a thickness of the protection layer is less than a height of the microlens structure.

5. The display module according to claim 1, wherein
a surface, distal from the base substrate, of the microlens structure is a curved surface; and
a distance between a side, distal from the base substrate, of the microlens structure and a side, distal from the base substrate, of the light-emitting pattern is equal to a radius of curvature of the microlens structure.

6. The display module according to claim 5, wherein
an orthographic projection of the microlens structure on a reference plane is curved, the reference plane being perpendicular to a bearing surface of the base substrate; and
a ratio of a height of the microlens structure to a width of the orthographic projection of the microlens structure on the reference plane ranges from 1/7 to 1/2.

7. The display module according to claim 1, further comprising: an encapsulation film layer disposed on the side, distal from the base substrate, of the plurality of light-emitting patterns, wherein the encapsulation film layer is configured to encapsulate the plurality of light-emitting patterns;
wherein a difference between a refractive index of the encapsulation film layer and a refractive index of the microlens structure is less than a difference threshold.

8. The display module according to claim 1, wherein in a same microlens group, an area of the orthographic projection of the gap on the base substrate is smaller than an area of an orthographic projection of the microlens structure on the base substrate.

9. The display module according to claim 1, wherein an orthographic projection of the microlens structure on the base substrate is not overlapped with the orthographic projection of the target region on the base substrate.

10. The display module according to claim 1, wherein the target region of the light-emitting pattern is doped with ions, and a conductivity of the target region is less than a conductivity of a region of the light-emitting pattern other than the target region.

11. The display module according to claim 10, wherein the ions comprise at least one of boron ions, phosphorus ions, argon ions, arsenic ions, and fluorine ions.

12. The display module according to claim 1, wherein at least one of the primary display regions comprises at least two sub-display regions acquired by being partitioned by the target region; and
a number of microlens structures included in a same microlens group is positively correlated with a number of sub-display regions acquired by partitioning the primary display region of the corresponding light-emitting pattern.

13. The display module according to claim 12, wherein the number of microlens structures included in the same microlens group is equal to the number of sub-display regions acquired by partitioning the primary display region of the corresponding light-emitting pattern.

14. The display module according to claim 1, wherein at least one of the primary display regions comprises at least two sub-display regions acquired by being partitioned by the target region; and
areas of orthographic projections of microlens structures included in a same microlens group on the base substrate are positively correlated with areas of orthographic projections of sub-display regions acquired by partitioning the primary display region of the corresponding light-emitting pattern.

15. The display module according to claim 1, wherein a number of microlens structures included in a same microlens group is positively correlated with an area of an orthographic projection of the primary display region of the corresponding light-emitting pattern on the base substrate.

16. The display module according to claim 15, wherein
the plurality of light-emitting patterns comprise a plurality of first color light-emitting patterns, a plurality of second color light-emitting patterns, and a plurality of third color light-emitting patterns; and
the plurality of microlens groups comprise a plurality of microlens groups in one-to-one correspondence to the plurality of first color light-emitting patterns, a plurality of second microlens groups in one-to-one correspondence to the plurality of second color light-emitting patterns, and a plurality of third microlens groups in one-to-one correspondence to the plurality of third color light-emitting patterns;
wherein each of the first microlens groups comprises an equal number of microlens structures, each of the second microlens groups comprises an equal number of microlens structures, and each of the third microlens groups comprises an equal number of microlens structures.

17. The display module according to claim 1, wherein
at least one of the primary display regions comprises at least two sub-display regions acquired by being partitioned by the target region; and
the display module further comprises a transistor device layer between the base substrate and the plurality of light-emitting patterns;
wherein a plurality of transistors included in the transistor device layer form a plurality of pixel circuits, a number of the pixel circuits is greater than or equal to a number of the light-emitting patterns, and the pixel circuit is configured to drive at least one of the sub-display regions in one of the light-emitting patterns to emit light.

18. A method for preparing a display module, comprising:
providing a base substrate;
forming a plurality of light-emitting patterns on the base substrate, wherein an orthographic projection region of at least one of the light-emitting patterns on the base substrate forms a primary display region;
forming a plurality of microlens groups corresponding to the plurality of light-emitting patterns on a side, distal from the base substrate, of the plurality of light-emitting patterns, wherein an orthographic projection of the microlens group on the base substrate is within the primary display region formed by corresponding the light-emitting pattern, the microlens group comprises at least two microlens structures, and a gap is defined between any adjacent two of the microlens structures in the microlens group; and
implanting ions into a target region of the light-emitting pattern using the microlens structure as a mask, wherein an orthographic projection of the target region on the base substrate is overlapped with an orthographic projection of the gap on the base substrate.

19. The method according to claim 18, upon implanting the ions into the target region of the light-emitting pattern, further comprising:
forming a protection layer on a side, distal from the base substrate, of the microlens structure; wherein
a refractive index of a material of the protection layer is less than a refractive index of the microlens structure, and the material of the protection layer comprises at least one of an inorganic material and a conductive light transmissive material; or
the material of the protection layer is a metallic material, and upon implanting the ions into the target region of the light-emitting pattern, the method further comprises: removing the protection layer.

20. A display device, comprising: a power supply assembly and a display module; wherein
the power supply assembly is configured to supply power to the display module; and
the display module comprises:
a base substrate;
a plurality of light-emitting patterns disposed on the base substrate, wherein an orthographic projection region of at least one of the light-emitting patterns on the base substrate forms a primary display region; and
a plurality of microlens groups corresponding to the plurality of light-emitting patterns, wherein the plurality of microlens groups are disposed on a side, distal from the base substrate, of the plurality of light-emitting patterns, an orthographic projection of the microlens group on the base substrate is within the primary display region formed by the corresponding light-emitting pattern, the microlens group comprises at least two microlens structures, and a gap is defined between any adjacent two of the microlens structures in the microlens group;
wherein the light-emitting pattern comprises a target region, wherein an orthographic projection of the target region on the base substrate is overlapped with an orthographic projection of the gap on the base substrate, and the target region does not emit light.
